(19) United States
(12) Patent Application Publication
(10) Pub. No.: US 2022/0238312 A1
(43) Pub. Date: Jul. 28, 2022

(54) SHOWERHEAD INSERT FOR UNIFORMITY TUNING

(71) Applicant: Lam Research Corporation, Fremont, CA (US)

(72) Inventor: David Michael French, Fort Myers, FL (US)

(21) Appl. No.: 17/612,536

(22) PCT Filed: Apr. 30, 2020
(86) PCT No.: PCT/US2020/030820

§ 371 Date: Nov. 18, 2021

Related U.S. Application Data
(60) Provisional application No. 62/854,193, filed on May 29, 2019.

(51) Int. Cl. H01J 37/32

(52) U.S. Cl. CPC H01J 37/32623; H01J 37/32724; H01L 21/67167; H01J 37/3244; H01J 37/32091

(57) ABSTRACT

In some examples, a shaped insert above a showerhead in a wafer processing chamber is used to alter the electric fields near the wafer processing area and in some examples to correct or improve asymmetry in a QSM processing module. In some embodiments, the insert may comprise an annular body, the annular body having at least one surface thereon that comprises a material for supporting electromagnetic coupling when energized by an RF power source, and an annulus in the annular body sized to accommodate a stem of the showerhead. In some examples, a configuration of the insert is selected to affect or correct an asymmetry of an electromagnetic field or plasma generated within the processing chamber in use.

### CLAIM OF PRIORITY

This application claims the benefit of priority to U.S. Patent Application Ser. No. 62/854,193, filed on May 29, 2019, which is incorporated by reference herein in its entirety.

### FIELD

The present disclosure relates to a showerhead insert and in some examples to a showerhead insert for a quad station process module (QSM) in semiconductor manufacturing applications.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Plasma systems are used to control plasma processes. A plasma system typically includes multiple radio frequency (RF) sources, an impedance match, and a plasma reactor. A workpiece (for example, a substrate or wafer) is placed inside the plasma chamber and plasma is generated within the plasma chamber to process the workpiece. It is often a key production goal for the workpiece to be processed in a uniform or repeatable manner. To this end, it can be important that electromagnetic field uniformity during wafer processing be achieved and consistently maintained. This can be particular challenging in asymmetric plasma chambers, for example.

### SUMMARY

The present disclosure relates generally to a showerhead insert (also called a showerhead liner), and in some applications to a showerhead insert for a QSM. One or more of the processing modules or stations in a QSM may be asymmetric. A shaped insert above the showerhead is used to alter the electric fields near the wafer processing area and in some examples to correct or improve asymmetry in a QSM processing module. In some embodiments, an insert for a showerhead in a processing chamber is provided. An example showerhead insert for may comprise: a body shaped and configured to associate with the showerhead in the processing chamber, the body having at least one surface thereon that comprises a material for supporting electromagnetic coupling when energized by an RF power source; and a formation in the body sized to accommodate a stem of the showerhead.

In some examples, a configuration of the insert is selected to affect or correct an asymmetry of an electromagnetic field or plasma generated within the processing chamber in use.

In some examples, the at least one surface of the insert includes a rounded or curved portion.

In some examples, the asymmetry is caused at least in part by a disconformity between a wall of the processing chamber, or an adjacent processing chamber, and a substrate-support assembly disposed therein, and wherein a profile of the rounded or curved portion of the at least one surface bounding the chamber substantially matches a profile of the substrate-support assembly.

In some examples, the body is an annular body, the formation in the body including an annulus of the annular body sized to accommodate the stem of the showerhead.

In some examples, the at least one surface extends into the annulus of the annular body.

In some examples, the at least one surface does not extend into the annulus of the annular body.

In some examples, the at least one surface covers a substantial entirety of the body of the insert.

In some examples, the least one surface of the insert is aligned in use with a wall or surface of the processing chamber or the showerhead.

In some examples, the least one surface of the insert is planar and in use is inclined in relation to a wall or surface of the processing chamber or the showerhead.

In some examples, the at least one surface of the insert modifies an internal geometry or volume of the processing chamber.

In some examples, the insert induces a substantially uniform electromagnetic field around a substrate-support assembly disposed within the processing chamber.

In some examples, the insert induces a substantially non-uniform electromagnetic field around a substrate-support assembly disposed within the processing chamber.

In some examples, the showerhead insert can be adjusted, repositioned, or mechanically modulated in shape or position to alter the electromagnetic field profile within the processing chamber.

In some embodiments, an insert for a showerhead in a processing chamber comprises a body shaped and configured to associate with the showerhead in the processing chamber, the body having at least one surface thereon that comprises a material for supporting electromagnetic coupling when energized by an RF power source; a formation in the body sized to accommodate a stem of the showerhead; the showerhead insert including an upper surface through which the stem of the showerhead can pass when the showerhead insert is fitted to the showerhead; and the showerhead insert including a shaped, recessed lower surface including at least one curved profile disposed adjacent, at least in part, a surface of the showerhead.

In some examples, the body is an annular body, the formation in the body including an annulus of the annular body sized to accommodate the stem of the showerhead.

In some examples, the shaped, recessed lower surface of the showerhead insert defines, at least in part, a free volume sized and configured to accept and surround a substantial entirety of the showerhead.

In some examples, a spatial distance between the shaped, recessed lower surface of the showerhead and an upper surface of the showerhead insert increases from a radially inner location to a radially outer location of the showerhead insert.

In some examples, the upper surface of the showerhead insert is substantially flat.

In some examples, a spatial distance between a wall of the annulus of the annular body and the stem of the showerhead increases from a vertically higher location to a vertically lower location of the showerhead insert.

### BRIEF DESCRIPTION OF THE DRAWINGS

Some embodiments are illustrated by way of example and not limitation in the views of the accompanying drawing:

FIGS. 1-4 show schematic views of substrate processing tools in which an example showerhead insert of the present disclosure may be deployed.

FIG. 5 is a schematic view of an example substrate processing tool including a quad station process module in which an example showerhead insert of the present disclosure may be deployed.

FIGS. 6A-6C depict an example electromagnetic field strength around a pedestal, according to an example embodiment.

FIG. 7 shows a simplified example of a plasma-based processing chamber, which can include a substrate-support assembly comprising an electrostatic chuck (ESC), having water-cooled components that may be used with the disclosed subject matter:

FIG. 8 shows a sectional side view of a showerhead, according to an example embodiment.

FIG. 9 shows a sectional side view of a showerhead to which a showerhead insert has been fitted, according to an example embodiment.

FIGS. 10A-10C show RF current paths, according to example embodiments.

FIGS. 11A-11B show top and underside pictorial views of a showerhead insert, according to an example embodiment.

### DESCRIPTION

The description that follows includes systems, methods, techniques, instruction sequences, and computing machine program products that embody illustrative embodiments of the present disclosure. In the following description, for purposes of explanation, numerous specific details are set forth in order to provide a thorough understanding of example embodiments. It will be evident, however, to one skilled in the art that the present disclosure may be practiced without these specific details.

A portion of the disclosure of this patent document may contain material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to any data as described below and in the drawings that form a part of this document: Copyright Lam Research Corporation, 2019, All Rights Reserved. Although a showerhead insert is described herein with particular reference to a QSM, this application is not limiting and, unless the context indicates otherwise, other applications are possible and are covered by the appended claims.

A substrate processing system may be used to perform deposition, etching and/or other treatment of substrates such as semiconductor wafers. During processing, a substrate is arranged on a substrate support in a processing chamber of the substrate processing system. During etching or deposition, gas mixtures including one or more etch gases or gas precursors, respectively, are introduced into the processing chamber and plasma may be struck to activate chemical reactions.

The substrate processing system may include a plurality of substrate processing tools arranged within a fabrication room. Each of the substrate processing tools may include a plurality of process modules. Typically, a substrate processing tool includes up to six process modules.

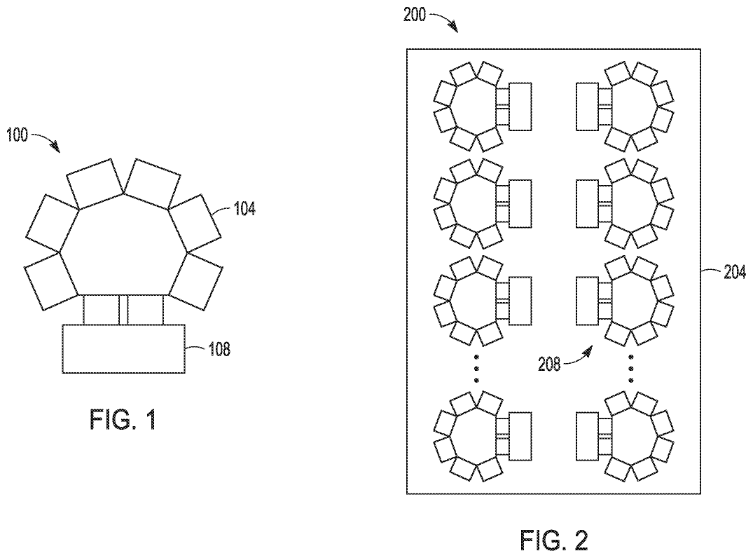

Referring now to FIG. 1, a top-down view of an example substrate processing tool 100 is shown. The substrate processing tool 100 includes a plurality of process modules 104. In some examples, each of the process modules 104 may be configured to perform one or more respective processes on a substrate. Substrates to be processed are loaded into the substrate processing tool 100 via ports of a loading station of an equipment front end module (EFEM) 108 and then transferred into one or more of the process modules 104. For example, a substrate may be loaded into each of the process modules 104 in succession. Referring now to FIG. 2, an example arrangement 200 of a fabrication room 204 including a plurality of substrate processing tools 208 is shown.

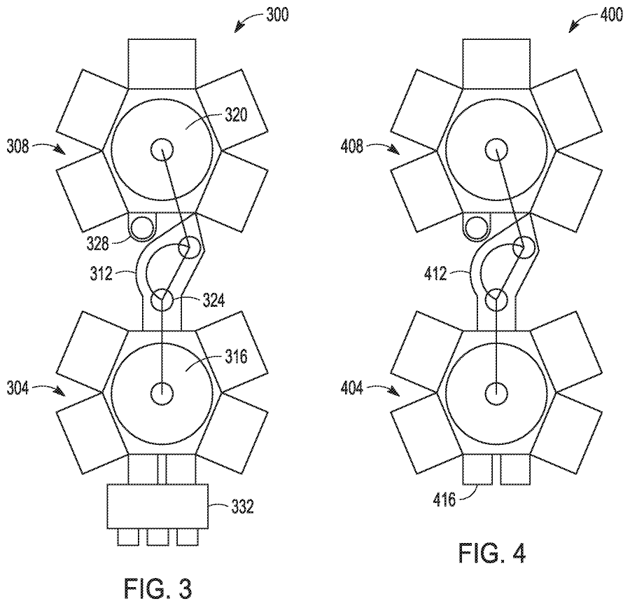

FIG. 3 shows a first example configuration 300 including a first substrate processing tool 304 and a second substrate processing tool 308. The first substrate processing tool 304 and the second substrate processing tool 308 are arranged sequentially and are connected by a transfer stage 312, which is under vacuum. As shown, the transfer stage 312 includes a pivoting transfer mechanism configured to transfer substrates between a vacuum transfer module (VTM) 316 of the first substrate processing tool 304 and a VTM 320 of the second substrate processing tool 308. However, in other examples, the transfer stage 312 may include other suitable transfer mechanisms, such as a linear transfer mechanism. In some examples, a first robot (not shown) of the VTM 316 may place a substrate on a support 324 arranged in a first position, the support 324 is pivoted to a second position, and a second robot (not shown) of the VTM 320 retrieves the substrate from the support 324 in the second position. In some examples, the second substrate processing tool 308 may include a storage buffer 328 configured to store one or more substrates between processing stages.

The transfer mechanism may also be stacked to provide two or more transfer systems between the substrate processing tools 308 and 304. Transfer stage 312 may also have multiple slots to transport or buffer multiple substrates at one time.

In the configuration 300, the first substrate processing tool 304 and the second substrate processing tool 308 are configured to share a single equipment front end module (EFEM) 332.

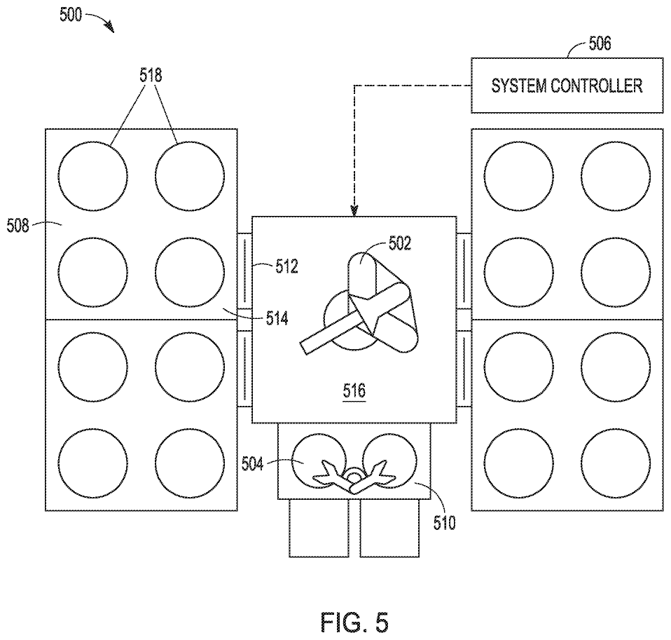

FIG. 4 shows a second example configuration 400 including a first substrate processing tool 404 and a second substrate processing tool 408 arranged sequentially and connected by a transfer stage 412. The configuration 400 is similar to the configuration 300 of FIG. 3 except that in the configuration 400, the EFEM 332 is eliminated. Accordingly, substrates may be loaded into the first substrate processing tool 404 directly via airlock loading stations 416 (e.g., using a storage or transport carrier such as a vacuum wafer carrier, front opening unified pod (FOUP), an atmospheric (ATM) robot, etc., or other suitable mechanisms).

A showerhead insert of the present disclosure may be deployed in quad station process modules (QSMs). In some examples, as shown in FIG. 5, a quad station process module 500 is provided. A QSM 500 includes four process modules 508 disposed at respective corner stations in the substrate processing tool 500. Each process module 508 may itself include four generally square corners, as shown. Each process module 508 has chamber walls enclosing four wafer processing stations 518 that may include generally round support pedestals, as shown. While various configurations of the process modules 508 are possible, in some examples the location of a round pedestal supporting a round wafer in a square (or non-matching) corner of a process module 508 is asymmetric and provides an asymmetric environment during wafer processing. This can present a significant challenge to electromagnetic uniformity and is at least one issue that embodiments of the present disclosure seek to address.

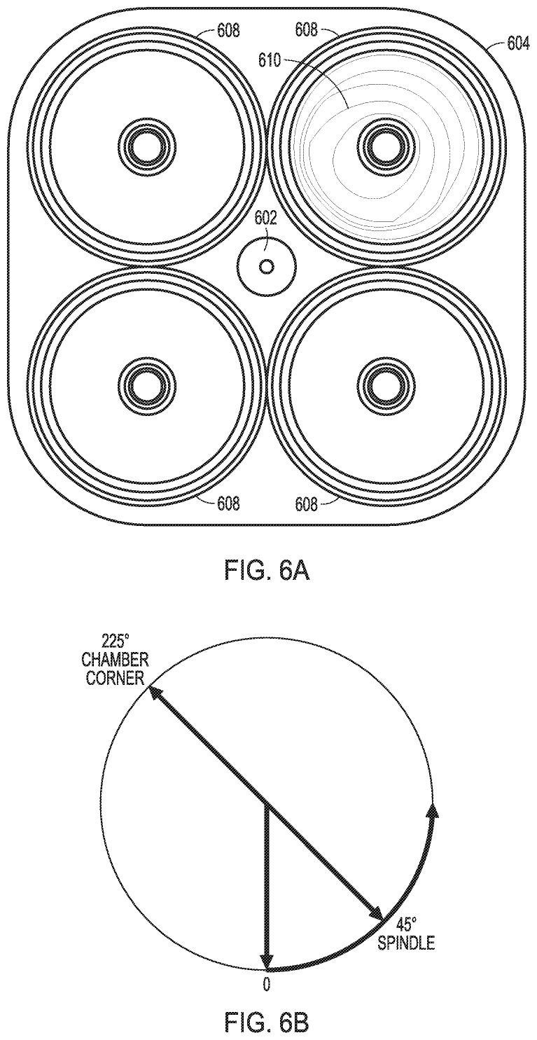

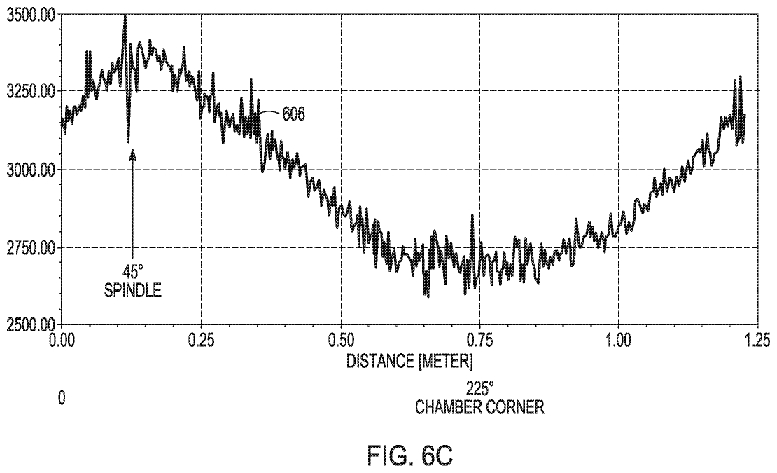

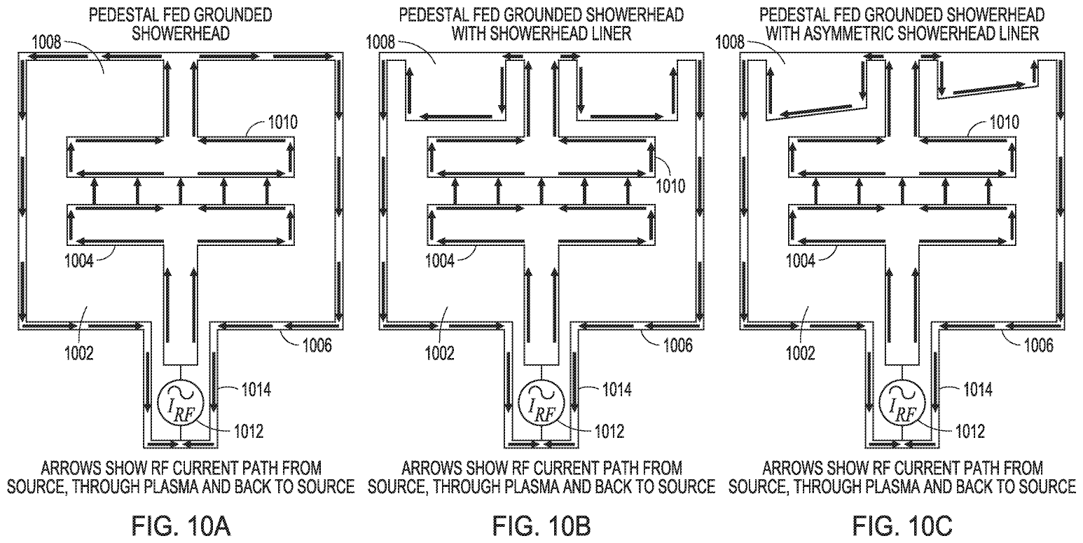

In this regard, reference is made to FIGS. 6A-6C. FIG. 6A shows a representation of varying electromagnetic field strength surrounding a round wafer processing station 518 in one of the four processing modules 508 of a QSM 500. The processing module 508 may have a chamber in an RF path (see for example, FIGS. 10A-10C below) that includes corners or other shapes. In the illustrated example, a wafer processing station 518 is not necessarily symmetric about the center of the wafer due to differing boundary conditions that may include a single chamber corner 604, a spindle region 602, and adjacent processing stations 608. The curved configuration of the rounded chamber corner 604 may substantially match the curved profile of the wafer processing station 518, but the adjacent stations 608 and spindle region 602 do not match the rounded pedestal profile. This uneven configuration can present an asymmetry in chamber geometry and cause the creation of an asymmetric electromagnetic field, as shown by contour lines 610. The asymmetric field is discussed further below.

Three radial positions around an example processing station 518 are shown in FIG. 6B at 0°, 45°, and 225° positions, respectively. The example processing station includes a chamber corner and spindle region as shown. Corresponding electromagnetic field strengths are shown for each of these three radial positions in the graph of FIG. 6C. The shape of the field strength line 606 indicates that the electromagnetic field strength fluctuates around the periphery of the pedestal 518. This may be caused primarily by the asymmetric geometry and environment of the processing module 508. This uneven or variable electromagnetic field distribution can present a significant challenge in obtaining uniform processing conditions across the surface of a wafer.

Returning to FIG. 5, the QSM 500 includes transfer robots 502 and 504, referred to collectively as transfer robots 502/504. The processing tool 500 is shown without mechanical indexers for example purposes. In other examples, the respective process modules 508 of the tool 500 may include mechanical indexers. A VTM 516 and an EFEM 510 may each include one of the transfer robots 502/504. The transfer robots 502/504 may have the same or different configurations. In some examples, the transfer robot 502 is shown as having two arms, with each arm having two vertically stacked end effectors. The robot 502 of the VTM 516 selectively transfers substrates to and from the EFEM 510 and between the process modules 508. The robot 504 of the EFEM 510 transfers substrates into and out of the EFEM 510. In some examples, the robot 504 may have two arms, each arm having a single end effector or two vertically stacked end effectors.

A system controller 506 may control various operations of the illustrated substrate processing tool 500 and its components including, but not limited to, operation of the robots 502/504, rotation of the respective indexers of the process modules 508, and so forth.

The tool 500 is configured to interface with, for example, each of the four process modules 508. Each process module 508 may have a single load station accessible via a respective slot 512. In this example, sides 514 of the VTM 516 are not angled (i.e., the sides 514 are substantially straight or planar). Other arrangements are possible. In the illustrated manner, two of the process modules 508, each having a single load station, are coupled to each of the sides 514 of the VTM 516. Accordingly, the EFEM 510 may be arranged at least partially between two of the process modules 508.

During substrate processing in a process module 508, processing gases enter the module to assist in creating a plasma, for example. The gases then exit the process module 508. The expulsion of exhaust gases may be performed by a vacuum or exhaust line. One of more exhaust lines may be situated underneath each processing module 508 and be connected to a vacuum source to expel gases from the process module 508.

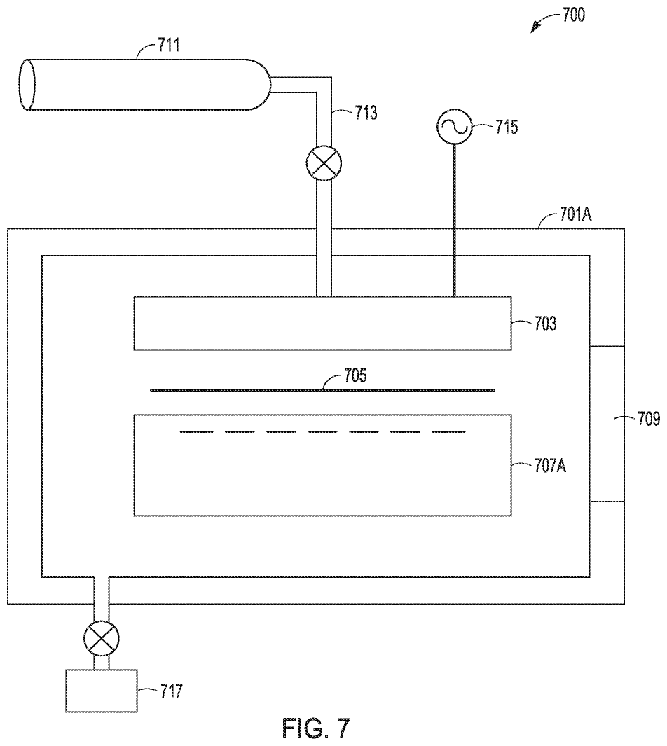

With reference now to FIG. 7, a simplified example of a plasma-based processing tool 700 is shown. FIG. 7 is shown to include the plasma-based processing chamber 701A in which a showerhead electrode (or for brevity simply called a showerhead) 703 and a substrate-support assembly 707A are disposed. The substrate-support assembly 707A may include a pedestal of the type discussed above. Typically, the substrate-support assembly 707A provides a substantially-isothermal surface and may serve as both a heating element and a heat sink for a substrate 705. The substrate-support assembly 707A may comprise an ESC in which heating elements are included to aid in processing the substrate 705, as described above. The substrate 705 may be a wafer comprising elemental semiconductors (e.g., silicon or germanium), a wafer comprising compound elements (e.g., gallium arsenide (GaAs) or gallium nitride (GaN)), or variety of other substrate types including conductive, semi conductive, and non-conductive substrates. The plasma-based processing chamber may have several water-cooled components.

In operation, the substrate 705 is loaded through a loading port 709 onto the substrate-support assembly 707A. A gas line 713 supplies one or more process gases to the showerhead electrode 703. In turn, the showerhead electrode 703 delivers the one or more process gases into the plasma-based processing chamber 701A. A gas source 711 to supply the one or more process gases is coupled to the gas line 713. An RF power source 715 is coupled to the showerhead electrode 703 or to the substrate-support assembly 707A (see FIGS. 10A-10C, for example).

In operation, the plasma-based processing chamber 701A is evacuated by a vacuum pump 717. RF power is capacitively coupled between the showerhead electrode 703 and a lower electrode (not shown explicitly) contained within or on the substrate-support assembly 707A. The substrate-support assembly 707A is typically supplied with two or more RF frequencies. For example, in various embodiments, the RF frequencies may be selected from at least one frequency at about 1 MHz, 2 MHz, 13.56 MHz, 27 MHz, 60 MHz, and other frequencies as desired. A coil to block or partially block a particular RF frequency can be designed as needed. Therefore, particular frequencies discussed herein are provided merely for ease in understanding. The RF power is used to energize the one or more process gases into a plasma in the space between the substrate 705 and the showerhead electrode 703. The plasma can assist in depositing various layers (not shown) on the substrate 705. In other applications, the plasma can be used to etch device features into the various layers on the substrate 705. As noted above, the substrate-support assembly 707A may have heaters (not shown) incorporated therein. RF power is coupled through at least the substrate-support assembly 707A.

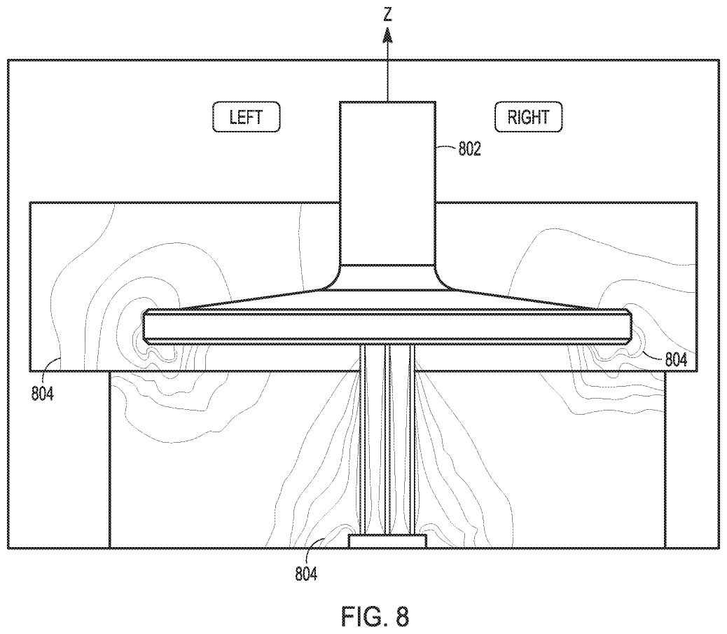

FIG. 8 shows a sectional side view of a showerhead 802, for example a showerhead 703 as discussed above. The illustrated showerhead 802 is energized by an external RF power source to create a number of example electric field contours 804 around it. It will be seen that the distribution pattern of the field contours 804 on the left of the pedestal 802 is different to the pattern on the right of the pedestal 802. The field contours on the left are more dispersed than their corresponding field contours on the right of the pedestal. This is an example of a non-uniform or asymmetric electromagnetic field. This processing chamber condition can significantly affect the creation of consistent semiconductor formations on the surface of a wafer.

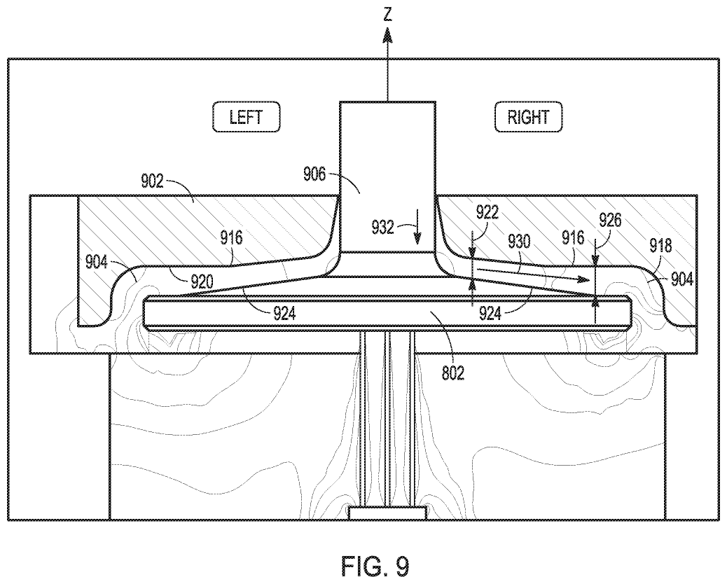

FIG. 9 shows the showerhead 802 to which an annular showerhead insert (also called a showerhead liner) 902 has been fitted. In this example, the showerhead insert has been fitted around the showerhead stem 906. Other arrangements are possible, for example by the insert 902 being supported by a wall of a processing chamber in which it is being used. Here, it will be noted that the distribution pattern of the field contours 904 is substantially the same on both the left and right sides of the showerhead 802. The showerhead insert 902 can provide an electromagnetic boundary condition which results in a more uniform electromagnetic field around the showerhead 802. Since the plasma in a processing chamber is created by an electromagnetic field generated in it, the resulting plasma is generally more uniform in distribution and effect.

In some examples, based on certain factors such as a processing chamber pressure, or a processing frequency, or a pedestal-to-showerhead gap, a gas composition, and other process parameters, the profile of a chamber surface (such as upper chamber wall, for example) can be configured by a showerhead insert. The size, shape and/or configuration of a showerhead insert may be selected and optimized to create or improve a more uniform and consistent formation creation on a wafer surface during processing. The use of a suitably shaped showerhead liner can enable consistent chamber conditions and allow wafer formation to be controlled and varied as desired.

In some examples, a showerhead insert 902 can induce a reduction in an undesired electromagnetic field above a showerhead which may otherwise ignite a parasitic plasma within a processing chamber. An appropriate insert shape or configuration can reduce the inductance of the RF path from the showerhead to the chamber walls which may reduce or alter a voltage of the showerhead relative to the chamber or a “ground” reference. A processing chamber geometry can be selected and adapted to impart a variety of processing conditions based on wafer processing needs.

In this regard, reference is now made to FIGS. 10A-10C. In some instances, it may be desired to correct an asymmetry in a wafer processing chamber such as in a wafer processing module 508, for example. In some examples, a specific asymmetry in a processing chamber may actually be desired. In each view, a wafer processing chamber 1002 is shown. The wafer processing chamber 1002 may be included in a processing module 508 in a QSM, for example. The processing chamber 1002 may be enclosed and defined by chamber walls 1006 including an upper chamber wall 1008 having an initially flat or unaltered surface or configuration. This configuration is shown in FIG. 10A.

Each processing chamber 1002 includes a substrate-support assembly 1004 which may include a round shaped pedestal 518 for example (FIG. 5-6), or 107A (FIG. 7). Each processing chamber 1002 further includes a showerhead 1010, such as a showerhead 802 (FIG. 8-9), or 703 (FIG. 7). Each processing chamber 1002 is powered by an RF power source 1012 (for example, RF power source 715 in FIG. 7) which can generate an electromagnetic field within each chamber 1002 to form a plasma 1018 between each substrate-support assembly 1004 and showerhead 1010. The arrows 1014 in each view of FIGS. 10A-10C show an RF current path generating an electromagnetic field in each processing chamber 1002. The RF current path proceeds from the RF power source 1012, through the plasma 1018 and back through the chamber walls 1006 and 1008 to the RF power source 1012.

A shape and strength of an electromagnetic field within the processing chamber 1002 may be configured by a showerhead insert. The showerhead insert may be configured appropriately to induce or adjust a symmetry or asymmetry of the electromagnetic field or plasma. In some examples, a chamber 1002 such as illustrated in FIG. 10A includes a pedestal-fed grounded showerhead 1010 which generates an RF current path, as shown.

In other examples, a chamber 1002 such as illustrated in FIG. 10B may include a pedestal-fed grounded showerhead 1010 and a symmetric annular showerhead insert 1016. The showerhead insert 1016 affects the RF current path 1014 as shown and alters the electromagnetic field in a manner to provide the desired symmetry which may beneficially impact a wafer supported by the substrate-support assembly 1004. In this example, the electromagnetic field is symmetric.

In further examples, a chamber 1002 such as illustrated in FIG. 10C includes a pedestal-fed grounded showerhead 1010 and an asymmetric showerhead insert 1016. The asymmetric showerhead insert 1016 affects the RF current path 1014 unequally as shown could be used to compensate for other asymmetries which may be present in a given RF plasma chamber such as a QSM 500. In this example, the electromagnetic field is asymmetric however it could be used to compensate for other asymmetries.

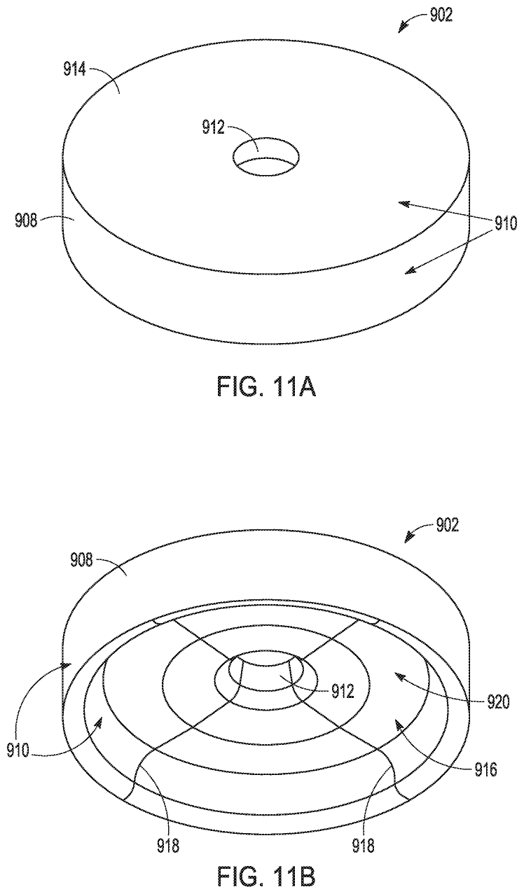

FIGS. 11A-11B provide top and underside pictorial views of an example configuration of a showerhead insert 902 for configuring an electromagnetic field within a processing chamber. With reference to FIGS. 11A-11B and FIG. 9, the showerhead insert 902 comprises a body 908 shaped and configured to associate with the showerhead in the processing chamber, for example a showerhead 802 in FIG. 9. The body 908 has one or more surfaces 910 that comprise a material for supporting electromagnetic coupling when energized by an RF power source. A formation 912 in the body 908 is sized to accommodate a stem of the showerhead, for example the showerhead stem 906 in FIG. 9. The showerhead insert 902 includes an upper surface 914 through which the stem (for example stem 906) of the showerhead can pass when the showerhead insert 902 is fitted to the showerhead (for example, showerhead 802). In some examples, the upper surface 914 of the showerhead insert 902 is substantially flat, as shown.

The showerhead insert 902 includes a shaped, recessed lower surface 916, also visible in sectional view in FIG. 9. The lower surface 916 includes at least one curved profile 918 disposed adjacent, at least in part, a surface of the showerhead 802. This may be more clearly seen in FIG. 9. In some examples, the body 908 of the showerhead insert 902 is an annular body, and the formation 912 in the body 908 includes an annulus 912 of the annular body 908. The annulus 912 is sized to accommodate the stem 906 of the showerhead 802, as shown in FIG. 9, for example.

The shaped, recessed lower surface 916 of the showerhead insert 902 defines, at least in part, an interior or free volume 920 sized and configured to accept and surround a substantial entirety of the showerhead 802, as shown more clearly in FIG. 9. In FIG. 9, it will be seen that in the illustrated example a spatial distance between the shaped, recessed lower surface 916 of the showerhead insert 902 and an upper surface 924 of the showerhead 802 increases from a radially inner location 922 to a radially outer location 926 of the showerhead insert 802 i.e. in the direction of arrow 930. In some examples, a spatial distance between a wall of the annulus 912 of the annular body 908 and the stem 906 of the showerhead 802 increases from a vertically higher location to a vertically lower location of the showerhead insert 902 i.e. in the direction of arrow 932.

Other showerhead insert 902 configurations are possible. Some example embodiments of a showerhead insert 902 may have one or more curved or rounded field-affecting surfaces. Other examples may further include one or more substantially planar field-affecting surfaces. A surface of a showerhead insert 902 may be aligned in use with a chamber wall or showerhead or be inclined with respect to these elements.

Although examples have been described with reference to specific example embodiments or methods, it will be evident that various modifications and changes may be made to these embodiments without departing from the broader scope of the embodiments. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

1. An insert for a showerhead in a processing chamber, the insert comprising:
a body shaped and configured to associate with the showerhead in the processing chamber, the body having at least one surface thereon that comprises a material for supporting electromagnetic coupling when energized by an RF power source; and
a formation in the body sized to accommodate a stem of the showerhead.

2. The showerhead insert of claim 1, wherein a configuration of the insert is selected to affect or correct an asymmetry of an electromagnetic field or plasma generated within the processing chamber in use.

3. The showerhead insert of claim 1, wherein the at least one surface of the insert includes a rounded or curved portion.

4. The showerhead insert of claim 3, wherein the asymmetry is caused at least in part by a disconformity between a wall of the processing chamber, or an adjacent processing chamber, and a substrate-support assembly disposed therein, and wherein a profile of the rounded or curved portion of the at least one surface bounding the chamber substantially matches a profile of the substrate-support assembly.

5. The showerhead insert of claim 1, wherein the body is an annular body, the formation in the body including an annulus of the annular body sized to accommodate the stem of the showerhead.

6. The showerhead insert of claim 5, wherein the at least one surface extends into the annulus of the annular body.

7. The showerhead insert of claim 5, wherein the at least one surface does not extend into the annulus of the annular body.

8. The showerhead insert of claim 1, wherein the at least one surface covers a substantial entirety of the body of the insert.

9. The showerhead insert of claim 1, wherein the least one surface of the insert is aligned in use with a wall or surface of the processing chamber or the showerhead.

10. The showerhead insert of claim 1, wherein the least one surface of the insert is planar and in use is inclined in relation to a wall or surface of the processing chamber or the showerhead.

11. The showerhead insert of claim 1, wherein the at least one surface of the insert modifies an internal geometry or volume of the processing chamber.

12. The showerhead insert of claim 1, wherein the insert induces a substantially uniform electromagnetic field around a substrate-support assembly disposed within the processing chamber.

13. The showerhead insert of claim 1, wherein the insert induces a substantially non-uniform electromagnetic field around a substrate-support assembly disposed within the processing chamber.

14. The showerhead insert of claim 1, which can be adjusted, repositioned, or mechanically modulated in shape or position to alter the electromagnetic field profile within the processing chamber.

15. An insert for a showerhead in a processing chamber, the insert comprising:
a body shaped and configured to associate with the showerhead in the processing chamber, the body having at least one surface thereon that comprises a material for supporting electromagnetic coupling when energized by an RF power source;
a formation in the body sized to accommodate a stem of the showerhead;
the showerhead insert including an upper surface through which the stem of the showerhead can pass when the showerhead insert is fitted to the showerhead; and
the showerhead insert including a shaped, recessed lower surface including at least one curved profile disposed adjacent, at least in part, a surface of the showerhead.

16. The showerhead insert of claim 15, wherein the body is an annular body, the formation in the body including an annulus of the annular body sized to accommodate the stem of the showerhead.

17. The showerhead insert of claim 16, wherein the shaped, recessed lower surface of the showerhead insert defines, at least in part, a free volume sized and configured to accept and surround a substantial entirety of the showerhead.

18. The showerhead insert of claim 17, wherein a spatial distance between the shaped, recessed lower surface of the showerhead insert and an upper surface of the showerhead increases from a radially inner location to a radially outer location of the showerhead insert.

19. The showerhead insert of claim 18, wherein the upper surface of the showerhead insert is substantially flat.

20. The showerhead insert of claim 19, wherein a spatial distance between a wall of the annulus of the annular body and the stem of the showerhead increases from a vertically higher location to a vertically lower location of the showerhead insert.
